(19) United States
(12) Patent Application Publication
(10) Pub. No.: US 2026/0122820 A1
(43) Pub. Date: Apr. 30, 2026

(54) AUTOMATION CONTROL SYSTEM COMPONENTS WITH INTERLOCKING FEATURES

(71) Applicant: Rockwell Automation Asia Pacific Business Center Pte. Ltd., Singapore (SG)

(72) Inventor: Soon Seng Kang, Singapore (SG)

(21) Appl. No.: 18/930,732

(22) Filed: Oct. 29, 2024

(51) Int. Cl. H05K 7/14; H01R 13/627

(52) U.S. Cl. CPC H05K 7/1469; H01R 13/6278; H05K 7/1465

(57) ABSTRACT

A system may include a base having one or more slots configured to receive one or more protrusions of a circuit of an input/output (I/O) module. The I/O module may include a first locking mechanism configured to couple to the base. The system may also include a terminal block with a coupling element configured to couple to a cylindrical element of the base, where the terminal block is configured to rotate about an axis defined by the cylindrical element via the coupling element. The terminal block may also include a second locking mechanism configured to couple to the I/O module and secure the terminal block to the I/O module.

### BACKGROUND

The present disclosure relates generally to the field of automation control systems, such as those used in industrial and commercial settings. More particularly, embodiments of the present disclosure relate to techniques for providing, accessing, configuring, operating, or interfacing with input/output (I/O) devices that are used for coupling and interaction with an automation controller.

Automation controllers may include special purpose computers used for controlling industrial automation and the like. Under the direction of stored programs, a processor of the automation controller examines a series of inputs (e.g., electrical input signals to the automation controller) reflecting the status of a controlled process and changes outputs (e.g., electrical output signals from the automation controller) based on analysis and logic for affecting control of the controlled process. The stored control programs may be continuously executed in a series of execution cycles, executed periodically, or executed based on events. The inputs received by the automation controller from the controlled process and the outputs transmitted by the automation controller to the controlled process are normally passed through one or more I/O devices, which may include components of an automation control system that may serve as an electrical interface between the automation controller and the controlled process.

Some I/O devices include a base that may couple the I/O device with a bus bar or the like, an I/O module that includes circuitry for performing communication functions and/or logic operations, a terminal block for communicatively coupling the I/O device with field devices, and the like. During operation, the I/O devices may be installed or mounted on a vertical surface, such that the force of gravity does not facilitate coupling between respective bases, I/O modules, and terminal blocks of the I/O devices. Additionally, the mounted I/O devices may experience vibrations due the controlled process (e.g., due to a number of operating devices). As a result, the bases, I/O modules, terminal blocks, and respective electrical connections may shift out of alignment during operation, which may cause unexpected control issues. It may be useful to provide features for preventing such misalignment of I/O device components.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, a system may include a base, an input/output (I/O) module, and a terminal block. The base may have one or more slots configured to receive one or more protrusions of a circuit of the I/O module. The I/O module may include a first locking mechanism configured to couple to the base. The terminal block may have a coupling element configured to couple to a cylindrical element of the base, where the terminal block is configured to rotate about an axis defined by the cylindrical element via the coupling element. The terminal block may also have a second locking mechanism configured to couple to the I/O module and secure the terminal block to the I/O module.

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 illustrates an example industrial automation system employed by a food manufacturer, in accordance with an embodiment;

FIG. 2 illustrates a diagrammatical representation of an exemplary control and monitoring system that may be employed in any suitable industrial automation system, in accordance with an embodiment;

FIG. 3 is a perspective view of a plurality of input/output (I/O) devices coupled to an I/O adapter, in accordance with an embodiment;

FIGS. 4 and 5 are perspective views of a base for use with an exemplary I/O device, in accordance with an embodiment;

FIG. 6 is a perspective view of the base being coupled to an additional base for use in coupling multiple I/O devices, in accordance with an embodiment;

FIG. 7 is a view of exemplary interlocking features of the bases of FIG. 6 for use in coupling multiple I/O devices, in accordance with an embodiment;

FIG. 8 is a perspective view of a locking mechanism in an unlocked position for use in coupling the bases of FIG. 6, in accordance with an embodiment;

FIG. 9 is a perspective view of the locking mechanism of FIG. 8 in a locked position, in accordance with an embodiment;

FIG. 10 is a perspective view of the base of the exemplary I/O device being coupled with an I/O module of the I/O device, in accordance with an embodiment;

FIG. 11 is a perspective view of the base of the exemplary I/O device coupled to the I/O module of the I/O device, with detailed views of exemplary interlocking features of the base and I/O module, in accordance with an embodiment;

FIG. 12 is an additional perspective view of the base of the exemplary I/O device being coupled with the I/O module of the I/O device, in accordance with an embodiment.

FIG. 13 is an additional perspective view of the base of the exemplary I/O device coupled with the I/O module of the I/O device, with a detailed view of an additional interlocking feature for use in coupling the base and the I/O module, in accordance with an embodiment;

FIG. 14 is a perspective view of a terminal block being coupled with the I/O module and base of the exemplary I/O device, in accordance with an embodiment;

FIG. 15 is a perspective view of an exemplary feature of the terminal block in an unlocked position for use in coupling the terminal block and the I/O module of the exemplary I/O device, in accordance with an embodiment;

FIG. 16 is a perspective view of the exemplary feature of the terminal block of FIG. 17 in a locked position, in accordance with an embodiment; and

FIG. 17 is a perspective view of the terminal block coupled to the base of the exemplary I/O device, without the I/O module and with detailed views of exemplary features of the base and the terminal block, in accordance with an embodiment.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation- specific decisions must be made to achieve the developers’ specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” “the,” and “said” are intended to mean that there are one or more of the elements. The terms “comprising,” “including,” and “having” are intended to be inclusive and mean that there may be additional elements other than the listed elements. As used herein, the terms “container nodes,” “host devices,” and “container hosts” may be used interchangeably. One or more specific embodiments of the present embodiments described herein will be described below. In an effort to provide a concise description of these embodiments, all features of an actual implementation may not be described in the specification.

As mentioned above, input/output (I/O) devices may experience forces (e.g., force of gravity, vibrations) that may interfere with electrical connections between respective components of the I/O devices (e.g., I/O modules, terminal blocks, bases), as well as interfere with electrical connections between the I/O devices and components of an industrial process (e.g., automation controller, field devices). As a result, unexpected control issues may arise. Therefore, the present disclosure is directed towards an I/O device assembly with interlocking features between components of the I/O device to securely fasten the components together, thereby reducing relative motion and maintaining proper electrical connections between the components. In some embodiments, a base of the I/O device may include coupling features to allow the base to securely fasten to one or more additional bases, thereby allowing a number of I/O devices to communicatively couple to each other as well as to other devices, such as network and/or power adapters, automation controllers, control systems, and the like. Further, a housing of the base may include one or more features (e.g., a number of protrusions, grooves, etc.) that may interface with one or more corresponding features of a housing of an I/O module of the I/O device. That is, the housings of the base and the I/O modules may include features to mechanically couple together and prevent relative motion between the base and the I/O module, thereby maintaining proper electrical connections between the base and the I/O module.

Additionally, a terminal block of the I/O device may include a coupling feature to mechanically and electrically couple to the base and the I/O module. Indeed, the terminal block may communicatively couple to the base via the I/O module, rather than independently couple to the base or a separate base. Therefore, aspects of the present disclosure may increase the flexibility of configuring I/O devices, as an increased number of terminal blocks and I/O modules may be used together interchangeably without needing to change out the base and/or add an additional base. That is, the I/O module of the I/O device may be replaced without needing to replace the terminal block or the base, and the terminal block may be replaced without needing to replace the I/O module or base, as the terminal blocks and I/O modules are compatible with the same bases.

In some embodiments, the I/O device may include a number of locking mechanisms between the components of the I/O device, as well as between components of the I/O device and components of additional I/O devices. For example, the base may include a locking mechanism to securely fasten to bases of additional I/O devices, the I/O module may include a locking mechanism to securely fasten to the base, and the terminal block may include a locking mechanism to securely fasten to the I/O module. The locking mechanisms may facilitate proper alignment and decrease shifting (e.g., relative motion) between components of the I/O device, thereby reducing unexpected control issues associated with signal interference from vibrations and the like. Additionally, the locking mechanisms may reduce the time and additional components (e.g., screws, bolts, washers, fasteners, etc.) needed to couple and decouple the components of the I/O device. For example, features of the locking mechanisms may be moved (e.g., pressed, slid, rotated, etc.) to engage and disengage the lock (e.g., rigid mechanical coupling) between components. Thus, components of the I/O device may be coupled and decoupled without specialized tools, additional components (e.g., fasteners), and the like.

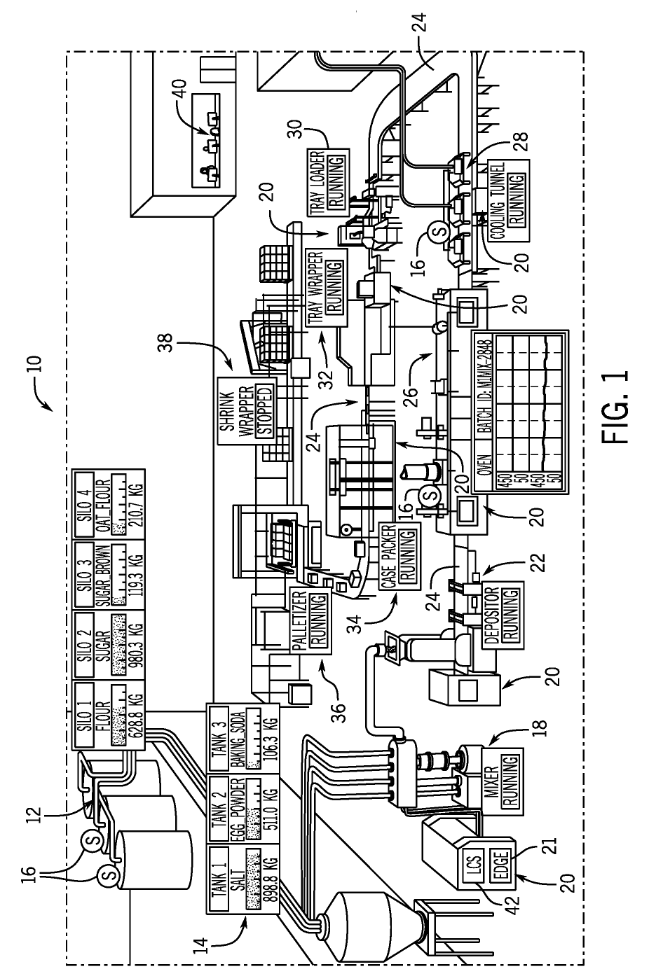

Accordingly, the present embodiments may improve operations of I/O devices (e.g., decrease a number of unexpected control issues) by maintaining proper mechanical and electrical connections between components of the I/O devices, as well as, increase the flexibility and decrease the complexity of assembling and configuring I/O devices. Additional details regarding the present embodiments described above will be detailed below with reference to FIGS. 1-17.

By way of introduction, FIG. 1 illustrates an example industrial automation system 10 employed by a food manufacturer. It should be noted that although the example industrial automation system 10 of FIG. 1 is directed at a food manufacturer, the present embodiments described herein may be employed within any suitable industry, such as automotive, mining, hydrocarbon production, manufacturing, and the like. The following brief description of the example industrial automation system 10 employed by the food manufacturer is provided herein to help facilitate a more comprehensive understanding of how the embodiments described herein may be applied to industrial devices to significantly improve the operations of the respective industrial automation system. As such, the embodiments described herein should not be limited to be applied to the example depicted in FIG. 1.

Referring now to FIG. 1, the example industrial automation system 10 for a food manufacturer may include silos 12 and tanks 14. The silos 12 and the tanks 14 may store different types of raw material, such as grains, salt, yeast, sweeteners, flavoring agents, coloring agents, vitamins, minerals, and preservatives. In some embodiments, sensors 16 may be positioned within or around the silos 12, the tanks 14, or other suitable locations within the industrial automation system 10 to measure certain properties, such as temperature, mass, volume, pressure, humidity, and the like.

The raw materials may be provided to a mixer 18, which may mix the raw materials together according to a specified ratio. The mixer 18 and other machines in the industrial automation system 10 may employ certain industrial automation devices 20 to control the operations of the mixer 18 and other machines. The industrial automation devices 20 may include controllers, input/output (I/O) modules, motor control centers, motors, human machine interfaces (HMIs), operator interfaces, contactors, starters, sensors 16, actuators, conveyors, drives, relays, protection devices, switchgear, compressors, sensor, actuator, firewall, network switches (e.g., Ethernet switches, modular-managed, fixed-managed, service-router, industrial, unmanaged, etc.) and the like.

The mixer 18 may provide a mixed compound to a depositor 22, which may deposit a certain amount of the mixed compound onto conveyor 24. The depositor 22 may deposit the mixed compound on the conveyor 24 according to a shape and amount that may be specified to a control system for the depositor 22. The conveyor 24 may be any suitable conveyor system that transports items to various types of machinery across the industrial automation system 10. For example, the conveyor 24 may transport deposited material from the depositor 22 to an oven 26, which may bake the deposited material. The baked material may be transported to a cooling tunnel 28 to cool the baked material, such that the cooled material may be transported to a tray loader 30 via the conveyor 24. The tray loader 30 may include machinery that receives a certain amount of the cooled material for packaging. By way of example, the tray loader 30 may receive 25 ounces of the cooled material, which may correspond to an amount of cereal provided in a cereal box.

A tray wrapper 32 may receive a collected amount of cooled material from the tray loader 30 into a bag, which may be sealed. The tray wrapper 32 may receive the collected amount of cooled material in a bag and seal the bag using appropriate machinery. The conveyor 24 may transport the bagged material to case packer 34, which may package the bagged material into a box. The boxes may be transported to a palletizer 36, which may stack a certain number of boxes on a pallet that may be lifted using a forklift or the like. The stacked boxes may then be transported to a shrink wrapper 38, which may wrap the stacked boxes with shrink-wrap to keep the stacked boxes together while on the pallet. The shrink-wrapped boxes may then be transported to storage or the like via a forklift or other suitable transport vehicle.

To perform the operations of each of the devices in the example industrial automation system 10, the industrial automation devices 20 may be used to provide power to the machinery used to perform certain tasks, provide protection to the machinery from electrical surges, prevent injuries from occurring with human operators in the industrial automation system 10, monitor the operations of the respective device, communicate data regarding the respective device to a supervisory control system 40, and the like. In some embodiments, each industrial automation device 20 or a group of industrial automation devices 20 may be controlled using a local control system 42. The local control system 42 may receive data regarding the operation of the respective industrial automation device 20, other industrial automation devices 20, user inputs, and other suitable inputs to control the operations of the respective industrial automation device(s) 20.

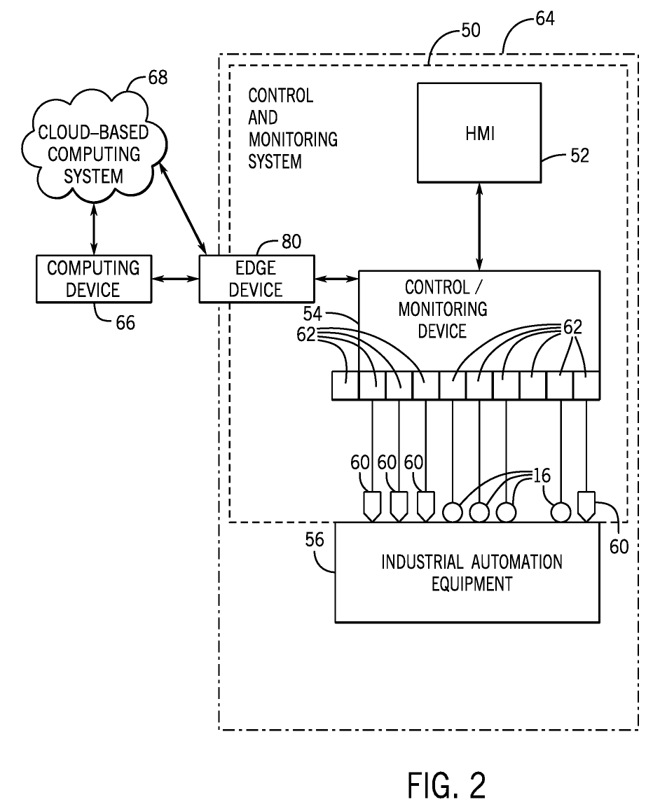

By way of example, FIG. 2 illustrates a diagrammatical representation of an exemplary control and monitoring system 50 that may be employed in any suitable industrial automation system 10, in accordance with embodiments presented herein. In FIG. 2, the control and monitoring system 50 is illustrated as including a human machine interface (HMI) 52 and a control/monitoring device 54 or automation controller adapted to interface with devices that may monitor and control various types of industrial automation equipment 56. By way of example, the industrial automation equipment 56 may include the mixer 18, the depositor 22, the conveyor 24, the oven 26, and the other pieces of machinery described in FIG. 1.

It should be noted that the HMI 52 and the control/monitoring device 54, in accordance with embodiments of the present techniques, may be facilitated by the use of certain network strategies. Indeed, an industry standard network may be employed, such as DeviceNet, to enable data transfer. Such networks permit the exchange of data in accordance with a predefined protocol, and may provide power for operation of networked elements.

As discussed above, the industrial automation equipment 56 may take many forms and include devices for accomplishing many different and varied purposes. For example, the industrial automation equipment 56 may include machinery used to perform various operations in a compressor station, an oil refinery, a batch operation for making food items, a mechanized assembly line, and so forth. Accordingly, the industrial automation equipment 56 may comprise a variety of operational components, such as electric motors, valves, actuators, temperature elements, pressure sensors, or a myriad of machinery or devices used for manufacturing, processing, material handling, and other applications.

Additionally, the industrial automation equipment 56 may include various types of equipment that may be used to perform the various operations that may be part of an industrial application. For instance, the industrial automation equipment 56 may include electrical equipment, hydraulic equipment, compressed air equipment, steam equipment, mechanical tools, protective equipment, refrigeration equipment, power lines, hydraulic lines, steam lines, and the like. Some example types of equipment may include mixers, machine conveyors, tanks, skids, specialized original equipment manufacturer machines, and the like. In addition to the equipment described above, the industrial automation equipment 56 may be made up of certain automation devices 20, which may include controllers, input/output (I/O) modules or devices, motor control centers, motors, human machine interfaces (HMIs), operator interfaces, contactors, starters, sensors 16, actuators, drives, relays, protection devices, switchgear, compressors, firewall, network switches (e.g., Ethernet switches, modular-managed, fixed-managed, service-router, industrial, unmanaged, etc.) and the like.

In certain embodiments, one or more properties of the industrial automation equipment 56 may be monitored and controlled by certain equipment for regulating control variables used to operate the industrial automation equipment 56. For example, the sensors 16 and actuators 60 may monitor various properties of the industrial automation equipment 56 and may adjust operations of the industrial automation equipment 56, respectively.

In some cases, the industrial automation equipment 56 may be associated with devices used by other equipment. For instance, scanners, gauges, valves, flow meters, and the like may be disposed on industrial automation equipment 56. Here, the industrial automation equipment 56 may receive data from the associated devices and use the data to perform their respective operations more efficiently. For example, a controller (e.g., control/monitoring device 54) of a motor drive may receive data regarding a temperature of a connected motor and may adjust operations of the motor drive based on the data.

In certain embodiments, the industrial automation equipment 56 may include a communication component that enables the industrial equipment 56 to communicate data between each other and other devices. The communication component may include a network interface that may enable the industrial automation equipment 56 to communicate via various protocols such as Ethernet/IP®, ControlNet®, DeviceNet®, or any other industrial communication network protocol. Alternatively, the communication component may enable the industrial automation equipment 56 to communicate via various wired or wireless communication protocols, such as Wi-Fi, mobile telecommunications technology (e.g., 2G, 3G, 4G, 5G, LTE), Bluetooth®, near-field communications technology, and the like.

The sensors 16 may be any number of devices adapted to provide information regarding process conditions. The actuators 60 may include any number of devices adapted to perform a mechanical action in response to a signal from a controller (e.g., the control/monitoring device 54). The sensors 16 and actuators 60 may be utilized to operate the industrial automation equipment 56. Indeed, they may be utilized within process loops that are monitored and controlled by the control/monitoring device 54 and/or the HMI 52. Such a process loop may be activated based on process inputs (e.g., input from a sensor 16) or direct operator input received through the HMI 52. As illustrated, the sensors 16 and actuators 60 are in communication with the control/monitoring device 54. Further, the sensors 16 and actuators 60 may be assigned a particular address in the control/monitoring device 54 and receive power from the control/monitoring device 54 or attached modules.

Input/output (I/O) modules or devices 62 may be added or removed from the control and monitoring system 50 via expansion slots, bays or other suitable mechanisms in accordance with embodiments described herein. In certain embodiments, the I/O modules 62 may be included to add functionality to the control/monitoring device 54, or to accommodate additional process features. For instance, the I/O modules 62 may communicate with new sensors 16 or actuators 60 added to monitor and control the industrial automation equipment 56. It should be noted that the I/O modules 62 may communicate directly to sensors 16 or actuators 60 through hardwired connections or may communicate through wired or wireless sensor networks, such as Hart or IOLink.

Generally, the I/O modules 62 serve as an electrical interface to the control/monitoring device 54 and may be located proximate or remote from the control/monitoring device 54, including remote network interfaces to associated systems. In such embodiments, data may be communicated with remote modules over a common communication link, or network, wherein modules on the network communicate via a standard communications protocol. Many industrial controllers can communicate via network technologies such as Ethernet (e.g., IEEE802.3, TCP/IP, UDP, Ethernet/IP, and so forth), ControlNet, DeviceNet or other network protocols (Foundation Fieldbus (H1 and Fast Ethernet) Modbus TCP, Profibus) and also communicate to higher level computing systems.

In the illustrated embodiment, several of the I/O modules 62 may transfer input and output signals between the control/monitoring device 54 and the industrial automation equipment 56. As illustrated, the sensors 16 and actuators 60 may communicate with the control/monitoring device 54 via one or more of the I/O modules 62 coupled to the control/monitoring device 54.

In certain embodiments, the control/monitoring system 50 (e.g., the HMI 52, the control/monitoring device 54, the sensors 16, the actuators 60, the I/O modules 62) and the industrial automation equipment 56 may make up an industrial automation application 64. The industrial automation application 64 may involve any type of industrial process or system used to manufacture, produce, process, or package various types of items. For example, the industrial applications 64 may include industries such as material handling, packaging industries, manufacturing, processing, batch processing, the example industrial automation system 10 of FIG. 1, and the like.

In certain embodiments, the control/monitoring device 54 may be communicatively coupled to a computing device 66 and a cloud-based computing system 68. In this network, input and output signals generated from the control/monitoring device 54 may be communicated between the computing device 66 and the cloud-based computing system 68. Although the control/monitoring device 54 may be capable of communicating with the computing device 66 and the cloud-based computing system 68, as mentioned above, in certain embodiments, the control/monitoring device 54 (e.g., local computing system 42) may perform certain operations and analysis without sending data to the computing device 66 or the cloud-based computing system 68.

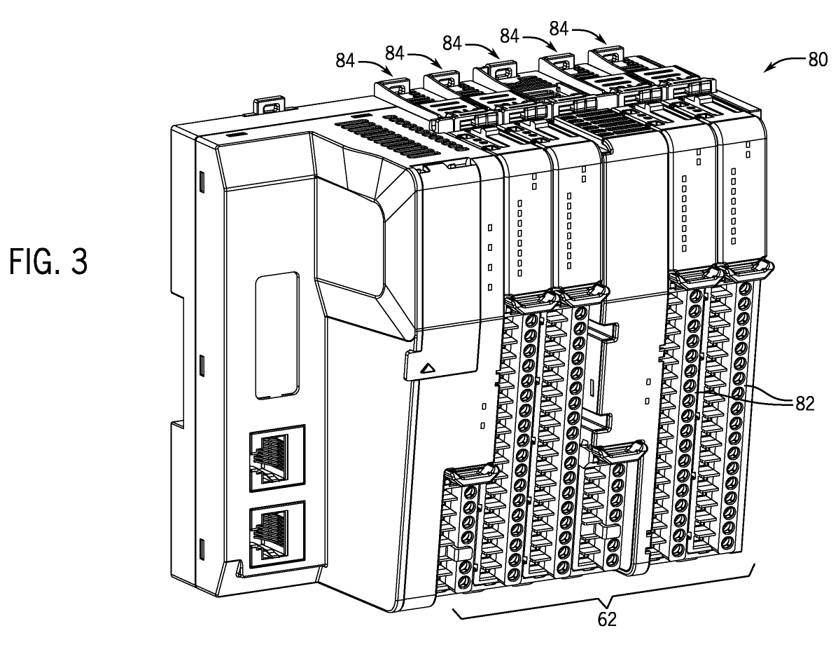

With the foregoing in mind, as mentioned above, the I/O modules 62 may be coupled to the control/monitoring device 54 via bays, electrical slots, expansion slots, and the like. By way of example, FIG. 3 illustrates a perspective view of a I/O module system 80 that may include a number of I/O modules 62. As illustrated, each I/O module 62 may include terminal blocks 82 that may couple to wires or other electrical components. Additionally, each I/O module 62 may include a base 84 that may communicatively couple the respective I/O module 62 to components within an industrial system 10 (e.g., the control/monitoring device 54) and to other I/O modules 62. The base 84 may be a mechanical structure with a coupling feature 86 (e.g., a pair of latches) that may couple to a rail (e.g., DIN rail) within an industrial system 10.

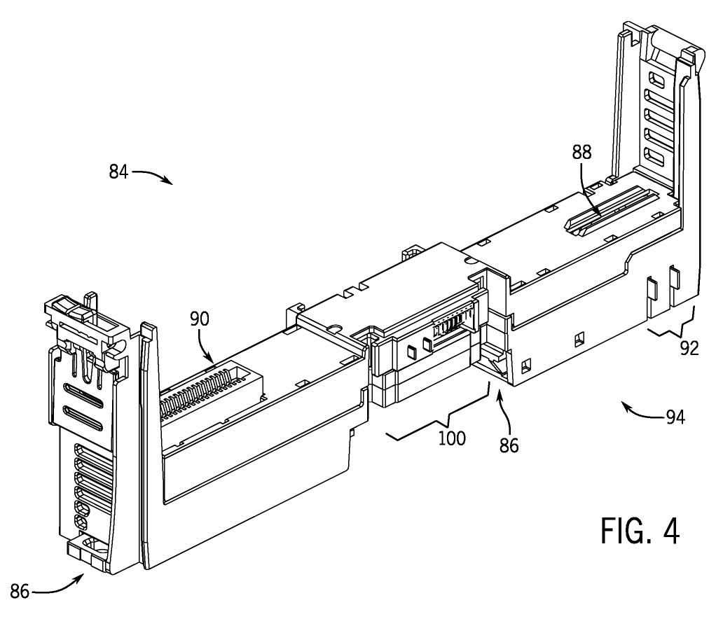

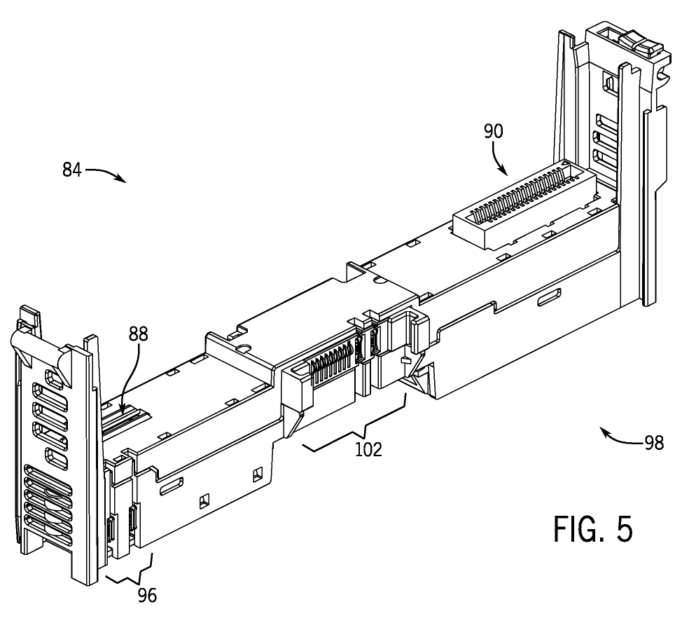

In some embodiments, the base 84 may include electrical slots that electrically and mechanically couple to circuitry (e.g., a circuit board) of the I/O module 62. The electrical slots may include a sensor actuator (SA) bus connector 88 and an I/O connector 90, as shown in FIGS. 4 and 5.

Referring to FIGS. 4 and 5, the base 84 may include an SA bus to electrically couple to a power source, such as a generator, rectifier, a battery (or other storage device), an external power grid, or the like. During operation, the I/O module 62 may receive power from the power source via the SA bus and the SA bus connector 88, and may selectively provide power to the sensors 16 and the actuators 60 via the terminal block 82. The SA bus may include protrusions 92 on a first side 94 of the base 84 (as shown in FIG. 4) and indentations 96 on a second side 98 of the base 84 (as shown in FIG. 5). The protrusions 92 and indentations 96 may have corresponding dimensions (e.g., length, width, height), such that the SA bus protrusions 92 of a first base may be inserted into the SA bus indentations 96 of a second base to electrically and mechanically couple the bases together. Accordingly, a number of I/O modules 62 may receive power from a shared power source via interconnected SA buses of their respective bases 84.

Further, the base 84 may include a multi-contact backplane connector with signal and power contacts to communicatively couple to other bases 84 and a network adapter. The backplane connector may include a plug or protrusion 100 on the first side 94 of the base 84 (as shown in FIG. 4) and a receptacle 102 on the second side 98 of the base 84 (as shown in FIG. 5), such that the plug 100 of a first base may be positioned or inserted into the receptacle 102 of a second base, and so on, thereby sequentially coupling a number of I/O devices and forming a backplane. The backplane may be communicatively coupled to a network adapter to transmit signals between the I/O modules 62 and a remote controller (e.g., control/monitoring device 54, a programmable logic controller or PLC). During operation, the I/O modules 62 may receive I/O signals from field devices (e.g., sensors 16, actuators 60) via the terminal blocks 82, process the I/O signals (e.g., authenticate the source of the signals, transform the signals, etc.), and send the I/O signals to the respective bases 84 via the I/O connectors 90. The bases 84 may include circuitry to encrypt the I/O signals, and may send the encrypted signals to the remote controller (e.g., directly or via the network adapter) via the backplane formed by interconnected backplane connectors (e.g., plugs or protrusions 100 and receptacles 102).

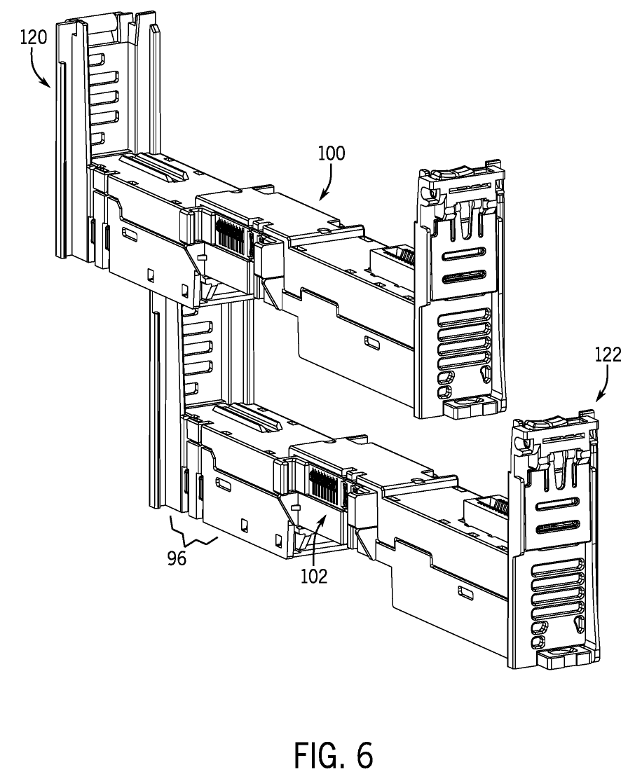

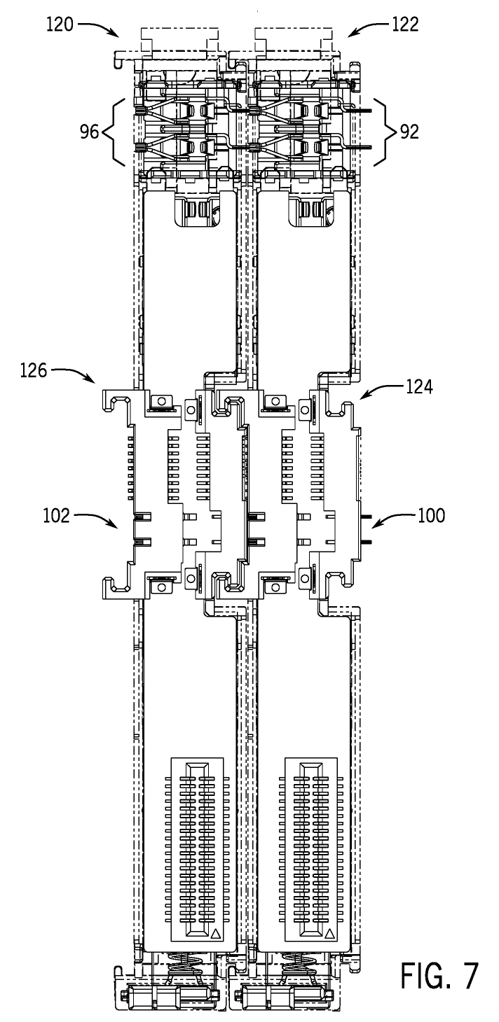

FIG. 6 illustrates a first base 120 aligned with a second base 122. As discussed above, the SA bus protrusions 92 of the first base 120 may be positioned into the SA bus indentations 96 of the second base 122, and the backplane connector plug 100 of the first base 120 may be positioned into the receptacle 102 of the second base 122 to electrically and mechanically couple the first base 120 and the second base 122 to one another. In some embodiments, the backplane connector of each base 84 may include mechanical features to limit relative movement between the first base 120 and the second base 122. For example, the backplane connector plug 100 may be proximate to one or more recess portions 124 (e.g., grooves, indentations, etc.) and the backplane connector receptacle 102 may be proximate to one or more protrusions 126, as shown in FIG. 7. The one or more recess portions 124 and the one or more protrusions 126 may have corresponding dimensions (e.g., length, width, height), such that the recess portions 124 and the protrusions 126 of neighboring bases 84 may interlock. FIG. 7 illustrates the recess portions 124 of the first base 120 interlocking with the protrusions 126 of the second base 122. Thus, interlocking features of the bases 84 may limit relative movement between the bases 84, and thus, may ensure proper electrical connections between each respective base 84 and one or more components of the industrial system 10 (e.g., other bases 84, I/O modules 62, power sources, network adapters, etc.), which may limit unexpected control issues associated with signal interference from vibrations and the like.

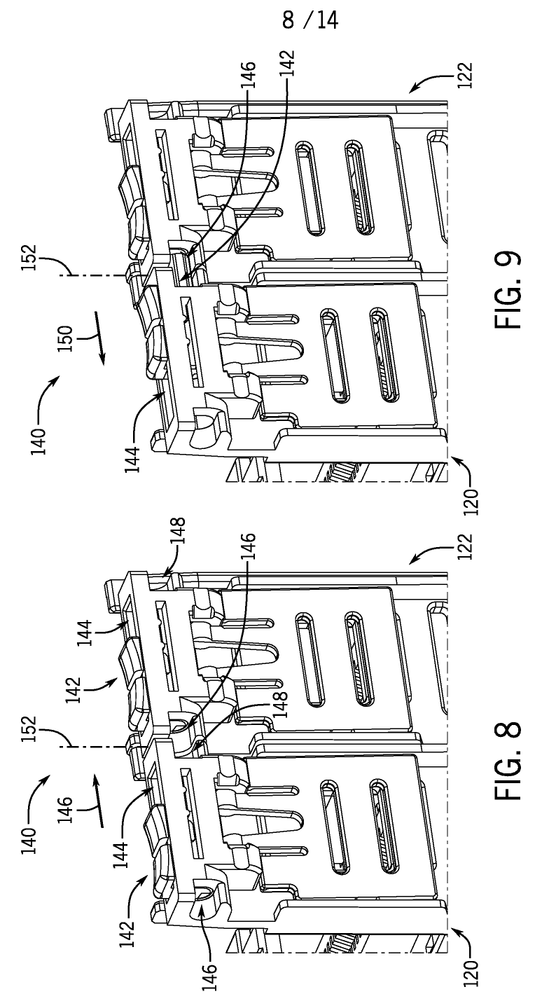

Further, in some embodiments, the base 84 may include a locking mechanism 140 to rigidly couple to neighboring bases 84, as shown in FIGS. 8 and 9. Referring closely to FIG. 8, each base 84 (e.g., first base 120 and second base 122) may include a pin 142 positioned within a track 144 (e.g., slot, bay, etc.) formed in a housing of the respective base. The housing may further include a groove 146 at or adjacent to one end of the track 144 and an opening 148 (e.g., aperture) on an opposite end of the track 144. As will be appreciated, the groove 146 and the opening 148 may have dimensions (e.g., length, width, height, diameter, etc.) that correspond to dimensions of the pin 142. For example, when the first base 120 and the second base 122 are aligned and coupled (e.g., via respective SA buses and backplane connectors), a pin 142 of the first base 120 may move (e.g., slide) within a respective track 144 in a direction 149 towards the second base 122 to extend through a respective opening 148 and into a groove 146 of the second base 122 to transition from an unlocked position, shown in FIG. 8, to a locked position, shown in FIG. 9. The pin 142 of the first base 120 may move in an additional direction 150 (e.g., opposite of direction 149) to transition from the locked position, shown in FIG. 9, to the unlocked positioned, shown in FIG. 8. While FIGS. 8 and 9 show two bases being locked together, any number of additional bases 84 (e.g., 1, 2, 3, 4, etc.) may be coupled and locked together via respective locking mechanisms 140 in the same manner described above. In this way, the locking mechanisms 140 of the bases 84 may limit relative motion between the bases 84 during operation. For example, the locking mechanisms 140 of the bases 84 in the I/O module system 80 of FIG. 3 may prevent relative movement between the bases 84 along an axis 152 (e.g., in a direction towards/away from a vertical surface the I/O module system 80 is mounted on), and thus, may facilitate maintaining proper alignment between the respective bases 84, I/O modules, and terminal blocks 82.

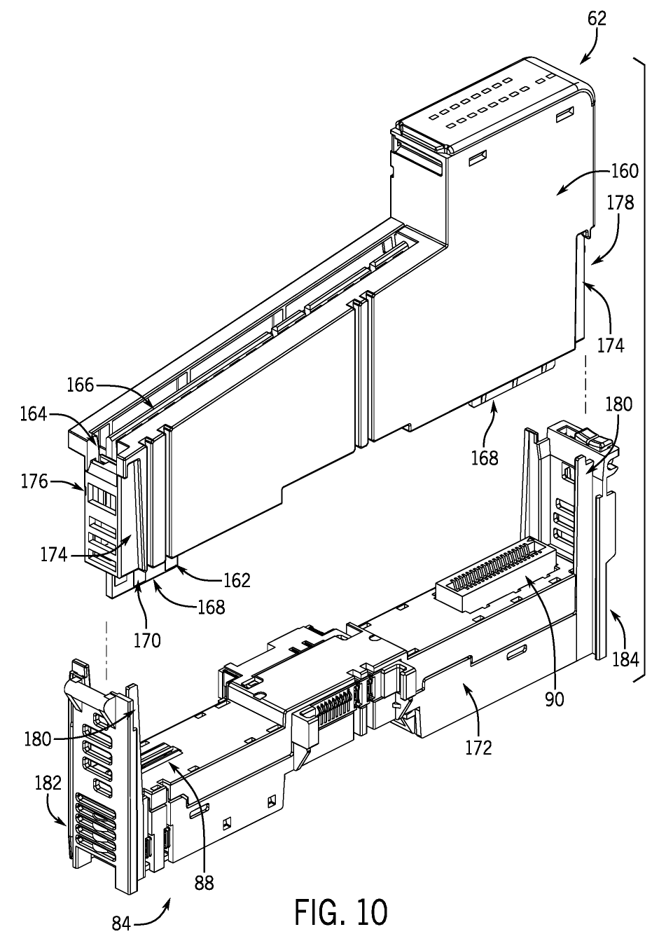

FIG. 10 illustrates the base 84 aligned with an I/O module 62. The I/O module 62 may include a housing 160 that may enclose or surround a circuit device 162. The housing 160 may be composed of plastic, metal, or other suitable material to protect the circuit device 162. In some embodiments, the housing 160 may include a receptacle 164 that may position the circuit device 162 therebetween.

The circuit device 162 may be a circuit board (e.g., printed circuit board) or another suitable piece of circuitry. In some embodiments, the circuit device 162 may include electrical connectors 166 (e.g., trace ends, board-to-board connectors) that may be positioned in the center or within the receptacle 164. The circuit device 162 may also include protrusions 168 that may be inserted or positioned within a bay, socket, slot, additional receptacle, or the like to connect to devices coupled to the I/O module system 80. The protrusions 168 may also include electrical connectors 170 that electrically couple to the control/monitoring device 54, the industrial automation equipment 56, or the like.

For example, the electrical connectors 170 may electrically and mechanically couple to electrical slots of the base 84, such as the SA bus connector 88 and the I/O connector 90. The SA bus connector 88 and the I/O connector 90 may each have dimensions that enable protrusions 168 having the electrical connectors 170 to position themselves into the available empty spaces of the SA bus connector 88 and the I/O connector 90, respectively, while making an electrical connection to the base 84 and other devices that may be connected to the base 84. Moreover, the insertion of the protrusions 168 into the electrical slots of the base 84 (e.g., SA bus connector 88, I/O connector 90) may securely fasten the electrical connectors 170 to corresponding electrical connectors of the base 84, and thus connecting the circuit device 162 to the base 84. In some embodiments, the circuit device 162 may receive power from a power source via the electrical connection between the electrical connectors 170 of the circuit device 162 and electrical connectors of the SA bus connector 88, and may transmit and receive I/O signals from a remote controller (e.g., control/monitoring device, a programmable logic controller or PLC) via the electrical connection between the electrical connectors 170 of the circuit device 162 and electrical connectors of the I/O connector 90.

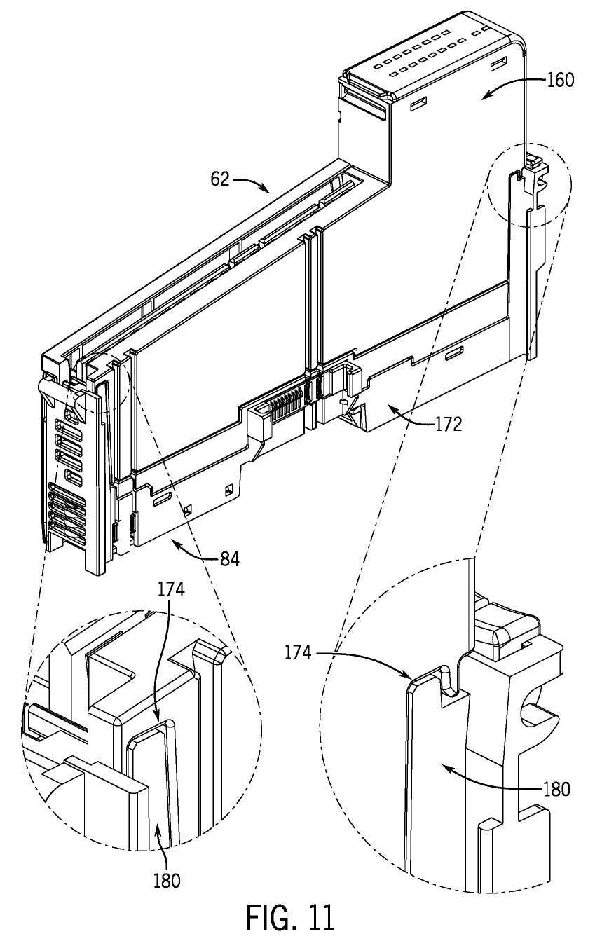

In some embodiments, the housing 160 of the I/O module 62 and a housing 172 of the base 84 may include interlocking features to limit relative movement between the I/O module 62 and the base 84, as shown in FIGS. 10 and 11. For example, the housing 160 of the I/O module 62 may include one or more indentations 174 (e.g., recess portions, slots, grooves) on or adjacent to a first end 176, a second end 178, or both, of the housing 160 (e.g., on one or more corners of the housing 160). The one or more indentations 174 may have a shape and dimensions (e.g., depth, width, length) corresponding to one or more protrusions 180 (e.g., tabs, ribs, extensions) on or adjacent to corresponding sides of the housing 172 of the base 84 (e.g., a first side 182, a second side 184, or both). Accordingly, the protrusions 180 may position themselves within the indentations 174 to mechanically couple the base 84 and the I/O module 62 together, as shown in FIG. 11. Referring closely to FIG. 11, the indentations 174 and the protrusions 180 may be substantially hook-shaped to increase the rigidity of the mechanical coupling (e.g., decrease relative motion) between the I/O module 62 and the base 84. Thus, interlocking features of the I/O module 62 and the base 84 may limit relative movement between the I/O module 62 and the base 84, and thus, may ensure proper electrical connections between the circuit device 162 of the I/O module and the electrical slots of the base 84 (e.g., SA bus connector 88, I/O connector 90), which may limit unexpected control issues associated with signal interference from vibrations and the like.

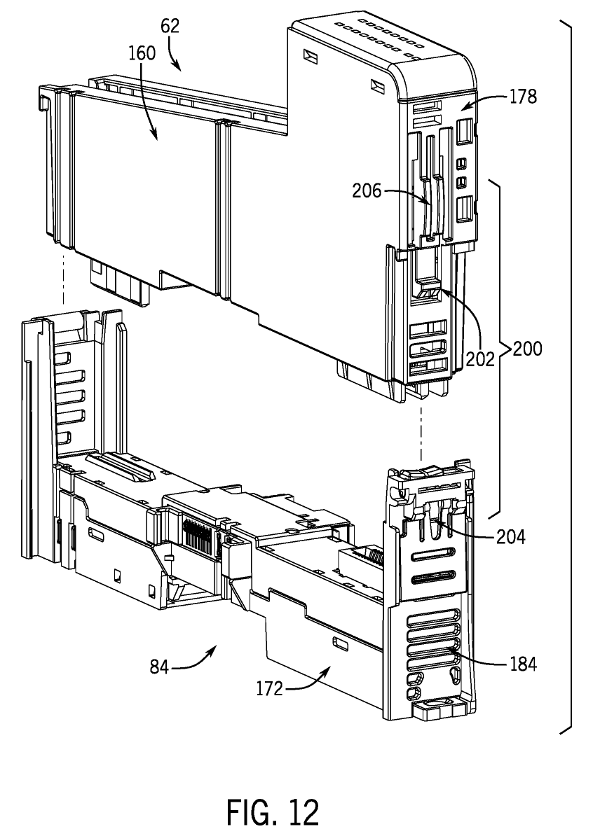

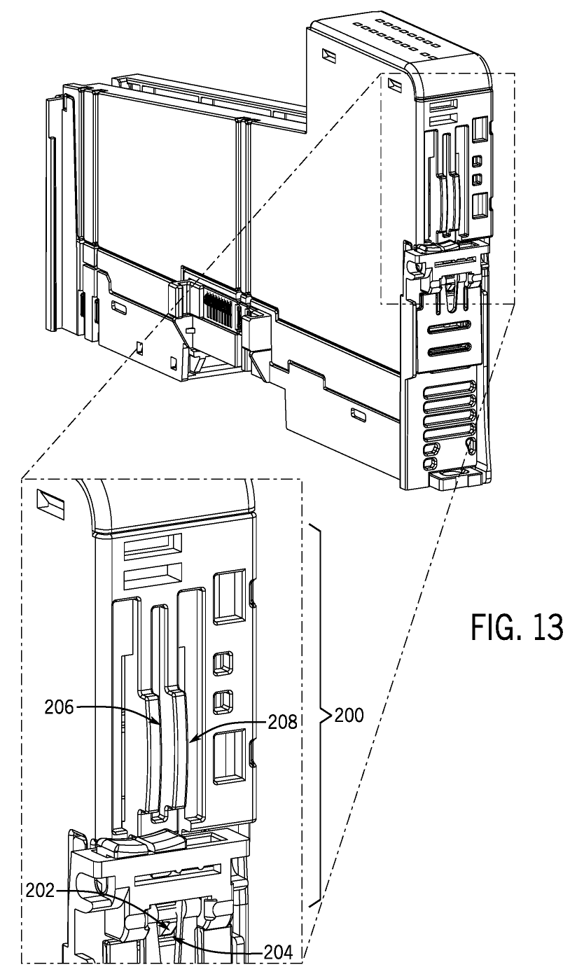

Further, in some embodiments, the I/O module 62 and the base 84 may include a locking mechanism 200 to rigidly couple together, as shown in FIGS. 12 and 13. The locking mechanism 200 may include a latch 202 formed in the housing 160 of the I/O module 62 (e.g., on the second end 178) and a slot 204 formed in the housing 172 of the base 84 (e.g., on the second end 184). The latch 202 may include a lever integrally formed with the housing 160 (e.g., formed using one or more cuts in the housing 160). Accordingly, when the I/O module 62 is positioned to couple with the base 84, the latch 202 may contact the housing 172 of the base 84 and retract (e.g., angle or rotate inward), before being inserted into the slot 204, where the latch 202 will rotate outward due to a loss of contact with the housing 172. The latch 202 and the slot 204 may have corresponding dimensions (e.g., length, width, etc.), such that inner surfaces of the slot 204 may interface with the latch 202, thereby securely fastening I/O module 62 to the base 84, as shown in FIG. 13. Therefore, the locking mechanism 200 may facilitate proper alignment between the I/O module 62 and the base 84, and decrease shifting (e.g., relative motion) between the I/O module 62 and the base 84, thereby reducing unexpected control issues associated with signal interference from vibrations and the like. Additionally, the locking mechanism 200 may reduce the time and components (e.g., screws, bolts, washers, fasteners, etc.) needed to couple and decouple the I/O module 62 from the base 84. For example, the lever 206 of the latch 202 may include one or more raised portions 208. Applying pressure (e.g., pressing) on the raised portions 208 may cause the latch 202 to angle and disengage with the slot 204, allowing the I/O module 62 to be removed from the base 84. Thus, the I/O module 62 and the base 84 may be coupled and decoupled without specialized tools, additional components (e.g., fasteners), and the like.

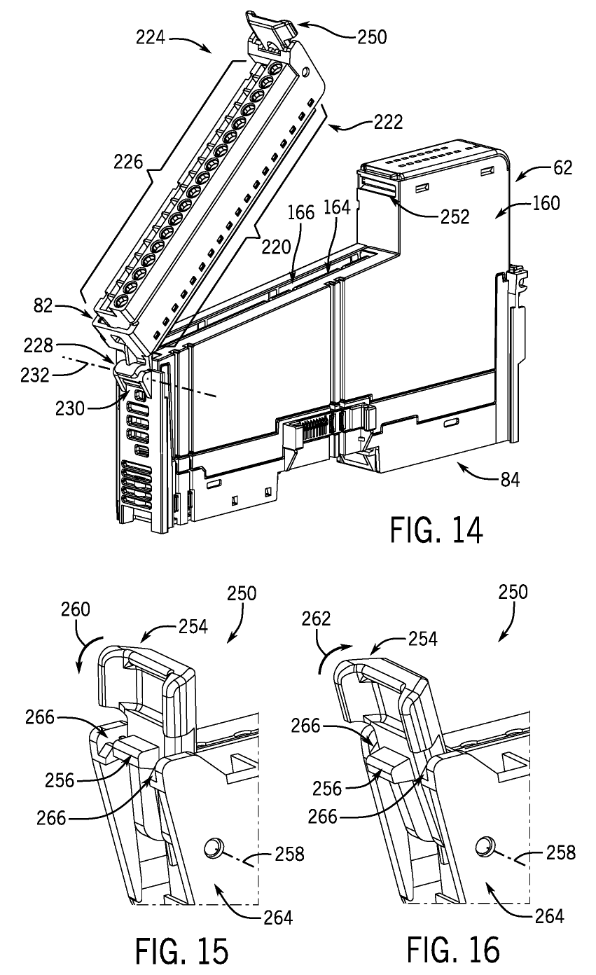

FIG. 14 illustrates a terminal block 82 being coupled with the I/O module 62 and the base 84. The terminal block 82 may include any suitable number (e.g., 8, 10, 16, 18, 20) of slots 220 on a first side 222 of the terminal block 82. Each of the slots 220 may be positioned such that it aligns with one of the electrical connectors 166 (e.g., trace ends, board-to-board connectors) of the circuit device 162. That is, the side 222 of the terminal block 82 may be coupled or affixed to a side of the circuit device 162 via the receptacle 164. With this in mind, a second side 224 (e.g., opposite of side 222) of the terminal block 82 may include terminals 226 that may electrically couple to the electrical connectors 166 of the circuit device 162 after the terminal block 82 is inserted into the receptacle 164. Further, the terminals 226 may couple to wires or other electrical components to communicatively couple the I/O module 62, via the terminal block 82, to components of an industrial system 10, such sensors 16, actuators 60, industrial automation equipment 56, and the like.

The terminal block 82 may communicatively couple to the base 84 via the I/O module 62 (e.g., via electrical connections with the circuit device 162), rather than independently couple to the base 84 or a separate base. As such, an increased number of terminal blocks 82 and I/O modules 62 may be used together interchangeably without needing to change out the base 84 and/or add an additional base. That is, the I/O module 62 may be replaced without needing to replace the terminal block 82 or the base 84, and the terminal block 82 may be replaced without needing to replace the I/O module 62 or base 84, as the terminal blocks 82 and I/O modules 62 are compatible with the same bases 84.

In some embodiments, the terminal block 82 may include a rotational coupling feature or element 228 that may be mechanically coupled to a coupling feature that may be part of the base 84 or housing 160 of the I/O module. The rotational coupling element 228 may have a circular shape with an aperture or empty portion of the circle to enable the rotational coupling element 228 to mechanically couple to a corresponding cylindrical feature or element. For example, the base 84 may include a fixed cylindrical element 230 that may mechanically couple to the rotational coupling element 228. The rotational coupling element 228 may be inserted (e.g., via missing circular portion) into the fixed cylindrical element 230. As such, the diameter of the fixed cylindrical element 230 may substantially match or be the same as the diameter of the circular shape of the rotational coupling element 228. After the rotational coupling element 228 is inserted into the fixed cylindrical element 230, the rotational coupling element 228 may rotate about an axis 232 that corresponds to the fixed cylindrical element 230. In this arrangement, the side 222 of the terminal block 82 may be positioned such that it rotates and aligns to be placed into the receptacle 164. As such, the terminal block 82 may be securely fastened to the housing 160 of the I/O module 62 and the circuit device 162, as well as the base 84.

Although the terminal block 82 is described as including a rotational coupling element 228 and the base 84 is described as including the fixed cylindrical element 230, it should be noted that any suitable coupling element(s) may be employed to securely fasten the terminal block 82 to the base 84 and I/O module 62 in accordance with embodiments described herein and should not be limited to the rotational coupling element 228 and fixed cylindrical element 230 illustrated herein.

Additionally, the terminal block 82 may include a locking mechanism 250 to rigidly couple to the I/O module 62, as shown in FIGS. 15 and 16. By way of example, the locking mechanism 250 may interface with a corresponding slot 252 (shown FIG. 14) formed in housing 160 of the I/O module 62. The locking mechanism 250 may include a rotational arm 254 with an extension 256 to enable the locking mechanism 250 to mechanically couple to the slot 252. As such, the extension 256 may have a matching shape or substantially the same dimensions (e.g., length, width, height, etc.) as the slot 252. After the terminal block 82 is rotated and placed in the receptacle 164, the rotational arm 254 of the locking mechanism 250 may pivot or rotate about an axis 258 (e.g., axis 232) in a first direction 260 (e.g., towards the I/O module 62), such that the extension 256 is inserted or placed into the slot 252 to transition from an unlocked position (shown in FIG. 15) to a locked position (shown in FIG. 16). As such, the terminal block 82 may be rigidly coupled to the I/O module 62 via the locking mechanism 250 to reduce or prevent relative movement between the terminal block 82 and the I/O module 62, thereby reducing unexpected control issues associated with signal interference from vibrations and the like.

Further, the locking mechanism 250 may reduce the time and components (e.g., screws, bolts, washers, fasteners, etc.) needed to couple and decouple the terminal block 82 from the I/O module 62. For example, the rotational arm 254 of the locking mechanism 250 may pivot or rotate about the axis 258 in a second direction 262 (e.g., opposite direction 260, away from the I/O module 62) to remove the extension 256 from the slot 252 and to transition from the locked position (shown in FIG. 16) to the unlocked position (shown in FIG. 15). After the locking mechanism 250 is unlocked, the rotational coupling element 228 may rotate about the axis 232 that corresponds to the fixed cylindrical element 230. In this arrangement, the side 222 of the terminal block 82 may be positioned such that it rotates to be removed from the receptacle 164. Thus, the terminal block 82 and the I/O module 62 may be coupled and decoupled without specialized tools, additional components (e.g., fasteners), and the like.

Additionally, inner surfaces or sides of a housing 264 of the terminal block 82 may include a set of grooves or teeth 266 with dimensions corresponding to one or more features (e.g., grooves, teeth, etc.) on corresponding sides of the rotational arm 254 of the locking mechanism. That is, the housing 264 of the terminal block 82 and the rotational arm 254 may be formed to facilitate a ratcheting interaction between the housing 264 and the locking mechanism 250 such that the locking mechanism 250 remains in the unlocked position (shown in FIG. 15) and/or the locked position (shown in FIG. 16) until it is rotated or pivoted by an operator. Accordingly, the terminal block 82 may remain rigidly coupled to the I/O module 62 via the locking mechanism 250 when the I/O device is mounted on a wall or vertical surface.

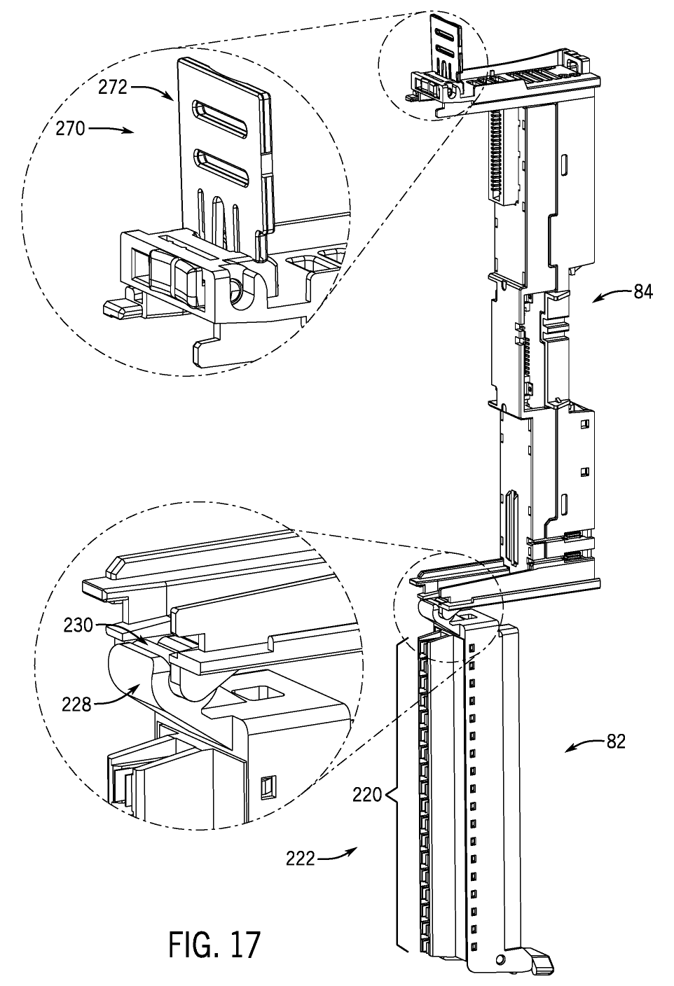

In some embodiments, the rotational coupling element 228 of the terminal block 82 and the fixed cylindrical element 230 may have corresponding dimensions to create a close fit between the rotational coupling element 228 and the fixed cylindrical element 230, allowing the rotational coupling element 228 to clip to the fixed cylindrical element 230. That is, the coupling between the rotational coupling element 228 and the fixed cylindrical element 230 may prevent the terminal block 82 from decoupling or free falling from the base 84. As discussed above, the I/O device including the base 84, I/O module 62, and terminal block 82 may be mounted on a wall or vertical surface. During operation, the rotational coupling element 228 may rotate about the axis 232 substantially 180 degrees and hang from the fixed cylindrical element 230, as shown in FIG. 17. As such, an operator may examine, replace, and/or perform maintenance on the I/O module 62 without decoupling the terminal block 82 from the base 84. Additionally, the operator may examine and/or perform maintenance on features of the terminal block 82, such as the slots 220 on the side 222 of the terminal block 82, without needing to fully remove the terminal block 82 from the I/O device. Therefore, features of the base 84 and terminal block 82 (e.g., rotational coupling element 228 and fixed cylindrical element 230) may prevent the terminal block 82 from being damaged, misplaced, and the like, during maintenance.

Further, the base 84 may include a billboard feature 270. A label identifying the respective base 84, I/O module 62, and terminal block 82 may be adhered to a side 272 of the billboard feature 270. In some embodiments, the label may additionally identify associated controlled processes and industrial automation equipment facilitated and serviced by the I/O device. The billboard feature 270 may be coupled to the base 84 in such a manner (e.g., via one or more hinges) to allow the billboard feature 270 to be rotated, flipped, or pivoted from a position flush against (e.g., contacting) a side of the base 84, to an upright position extending away from the base 84, and remain or stay in the upright position without any additional support. As such, operators may view the label on the billboard 270 without having to adjust or support the billboard 270, which may allow operators to quickly identify particular I/O devices and components of the I/O devices, and reduce the chances of terminal blocks 82 and I/O modules 62 being misplaced and/or coupled to incorrect bases 84.

With this in mind, aspects of the present disclosure may improve operations of I/O devices (e.g., decrease a number of unexpected control issues), as well as, increase the flexibility and decrease the complexity of assembling, disassembling, and configuring I/O devices. For example, interlocking features between components of an I/O device assembly (e.g., base 84, I/O module 62, terminal block 82) may securely fasten the components together, thereby reducing relative motion and maintaining proper electrical connections between the components. Further, in some embodiments, the I/O device may include a number of locking mechanisms between the components of the I/O device, as well as between components of the I/O device and components of additional I/O devices, that may facilitate proper alignment and decrease shifting (e.g., relative motion) between components of the I/O device, thereby reducing unexpected control issues associated with signal interference from vibrations and the like. Additionally, the locking mechanisms may reduce the time and additional components (e.g., fasteners, specialized tools) needed to assemble and disassemble the I/O device. In some embodiments, a terminal block of the I/O device may couple to a base of the I/O device via an I/O module of the I/O device, rather than independently couple to the base or a separate base, thereby increasing the flexibility of configuring the I/O device, as a number of terminal blocks and I/O modules may be used together interchangeably without needing to change out the base and/or add an additional base. Thus, embodiments of the present disclosure may aid in maintaining proper operations of I/O devices, while reducing the complexity of assembling, disassembling, and performing maintenance on I/O devices.

The techniques presented and claimed herein are referenced and applied to material objects and concrete examples of a practical nature that demonstrably improve the present technical field and, as such, are not abstract, intangible, or purely theoretical. Further, if any claims appended to the end of this specification contain one or more elements designated as “means for [perform]ing [a function]…” or “step for [perform]ing [a function]…”, it is intended that such elements are to be interpreted under 35 U.S.C. 112(f). However, for any claims containing elements designated in any other manner, it is intended that such elements are not to be interpreted under 35 U.S.C. 112(f).

While only certain features of the embodiments have been illustrated and described herein, many modifications and changes will occur to those skilled in the art. It is, therefore, to be understood that the appended claims are intended to cover all such modifications and changes as fall within the true spirit of the present embodiments describe herein.

1. A system, comprising:
a base comprising one or more slots configured to receive one or more protrusions of a circuit of an input/output (I/O) module;
the I/O module, wherein the I/O module comprises a first locking mechanism configured to couple to the base; and
a terminal block comprising:
a coupling element configured to couple to a cylindrical element of the base, wherein the terminal block is configured to rotate about an axis defined by the cylindrical element via the coupling element; and
a second locking mechanism configured to couple to the I/O module and secure the terminal block to the I/O module.

2. The system of claim 1, wherein the base comprises a third locking mechanism configured to couple the base to an additional base, wherein the third locking mechanism comprises a pin disposed within a track formed in a housing of the base, wherein the pin is configured to extend through an opening at an end of the track and interface with a groove on a corresponding end of the additional base.

3. The system of claim 2, wherein the base comprises a connector configured to couple to the additional base, wherein the connector comprises a protrusion on a first side of the base and a receptacle on a second side of the base, wherein the protrusion is configured to be inserted into an additional receptacle of the additional base, and wherein the receptacle is configured to receive an additional protrusion of the additional base.

4. The system of claim 1, wherein the first locking mechanism comprises a lever integrally formed with a housing of the I/O module, wherein the lever comprises one or more raised portions and a latch configured to interface with a slot formed in an additional housing of the base, wherein the one or more raised portions of the lever is configured to angle the latch into the slot.

5. The system of claim 1, wherein the second locking mechanism comprises an arm configured to pivot in a first direction to position an extension of the arm into a slot formed in a housing of the I/O module to prevent relative motion between the terminal block and the I/O module.

6. The system of claim 5, wherein the arm is configured to pivot in a second direction to remove the extension from the slot to allow relative motion between the terminal block and the I/O module.

7. The system of claim 1, wherein the base comprises a bus configured to couple to a power source, wherein the one or more slots comprise a bus connector configured to couple the I/O module to the power source.

8. The system of claim 1, wherein the one or more slots comprise a connector configured to communicatively couple the I/O module to the base.

9. A base, comprising:
one or more slots configured to couple to a circuit of an I/O module;
a connector configured to couple to an additional base; and
a locking mechanism configured to limit relative motion between the base and the additional base.

10. The base of claim 9, comprising a bus configured to couple to a power source, wherein the one or more slots comprise a bus connector configured to couple the I/O module to the power source.

11. The base of claim 10, wherein the bus comprises protrusions on a first side of the base and indentations on a second side of the base, wherein the protrusions are configured to be inserted into additional indentations of the additional base, and wherein the indentations are configured to receive additional protrusions of the additional base.

12. The base of claim 9, wherein the connector comprises a protrusion on a first side of the base and a receptacle on a second side of the base, wherein the protrusion is configured to be inserted into an additional receptacle of the additional base, and wherein the receptacle is configured to receive an additional protrusion of the additional base.

13. The base of claim 9, comprising a billboard feature configured to rotate to a position extending away from a surface of the base, wherein the billboard feature is configured to remain in the position.

14. The base of claim 9, comprising one or more latches configured to couple the base to a DIN rail.

15. The base of claim 9, comprising a cylindrical element configured to couple to a coupling element of a terminal block, wherein the terminal block is configured to rotate about an axis defined by the cylindrical element via the coupling element.

16. The base of claim 9, comprising a housing comprising a plurality of grooves configured to interlock with a plurality of indentations formed in an additional housing of the I/O module.

17. The base of claim 16, wherein the locking mechanism comprises a pin disposed within a track formed in the housing, wherein the pin is configured to extend through an opening at an end of the track and interface with a groove on a corresponding end of the additional base.

18. A method, comprising:
inserting one or more protrusions of a circuit of an input/output (I/O) module into one or more electrical slots of a base;
adjusting a position of a latch of a housing of the I/O module to secure the I/O module to the base, wherein the latch is configured to interface with a slot of the base;
coupling a coupling element of a terminal block to a cylindrical element of the base;
rotating the terminal block along an axis of the cylindrical element, wherein the terminal block is configured to couple to the circuit of the I/O module and to a housing of the I/O module via the rotation; and
pivoting an arm of a locking mechanism of the terminal block in a first direction, wherein the arm comprises an extension configured to couple to an additional slot formed in a housing of the I/O module via the pivot.

19. The method of claim 18, comprising:
inserting a protrusion of a connector of the base into a receptacle of an additional connector of an additional base, wherein the connector and the additional connector are configured to communicatively couple the base and the additional base;
positioning protrusions of a bus of the base into indentations of an additional bus of the additional base, wherein the bus and the additional bus are configured to electrically couple the base and the additional base to a power source; and
inserting a pin of a locking mechanism of the base into a groove of an additional locking mechanism of the additional base, wherein the locking mechanism and the additional locking mechanism are configured to secure the base to the additional base.

20. The method of claim 18, comprising:
coupling the base to a DIN rail;
rotating a billboard feature of the base to a position extending away from a surface the base, wherein the billboard feature is configured to remain in the position; and
adhering a label to the billboard feature, wherein the label is configured to identify the base, the I/O module, the terminal block, or any combination thereof.
